(19) United States
(12) Patent Application Publication
(10) Pub. No.: US 2014/0377507 A1
(43) Pub. Date: Dec. 25, 2014

(54) Composite Substrate Used For GaN Growth

(71) Applicant: Sino Nitride Semiconductor Co, LTD., DongGuan (CN)

(72) Inventors: Guoyi Zhang, Beijing (CN); Yongjian Sun, Beijing (CN); Yuzhen Tong, Beijing (CN)

(21) Appl. No.: 14/369,707

(22) PCT Filed: May 22, 2012
(86) PCT No.: PCT/CN2012/075853

§ 371 Date: Jun. 29, 2014

(30) Foreign Application Priority Data
Mar. 14, 2012 (CN) 201210068026.0

(51) Int. Cl. H01L 29/20

(52) U.S. Cl. CPC H01L 29/2003
USPC 428/172; 428/698; 428/215; 428/457; 428/446

(57) ABSTRACT

The present application discloses a composite substrate used for GaN growth, comprising a thermally and electrically conductive layer (1) with a melting point greater than 1000° C. and a mono-crystalline GaN layer 2 (2) located on the thermally and electrically conductive layer (1). The thermally and electrically conductive layer (1) and the mono-crystalline GaN layer 2 (2) are bonded through a van der Waals force or a flexible medium layer (3). The composite substrate can further include a reflective layer (4) located at an inner side, a bottom part, or a bottom surface of the mono-crystalline GaN layer 2. In the disclosed composite substrate, iso-epitaxy required by GaN epitaxy is provided; crystalline quality is improved; and a vertical structure LED can be directly prepared. Further, a thin mono-crystalline GaN layer 2 greatly reduces cost, which is advantageous in applications.

### BACKGROUND OF THE INVENTION

The present application relates to optoelectronic semiconductor devices, and in particular, to manufacturing technologies for fabricating such devices.

In recent years, III/V nitride materials, mainly GaN, InGaN, and AlGaN, have received much attention as semiconductor materials. The III/V nitride materials have direct band gaps that can be continuously varied from 1.9 to 6.2 eV, excellent physical and chemical stability, and high saturation electron mobility. They have become the preferred materials for optoelectronic devices such as laser devices and light-emitting diodes.

Due to a lack of GaN substrate, the present GaN-based semiconductor devices involves hetero-epitaxial growth of GaN layers on a substrate of a different material such as sapphire, SiC, and Si, wherein crystalline lattices of the GaN materials are highly mismatched to those of the substrate.

Among the above described substrate materials, sapphire is the most widely used. Sapphire substrate, however, is associated with the following problems: first, the large lattice mismatch and thermal stress between the epitaxially grown GaN and the sapphire substrate can produce high concentration of dislocations of about 10⁹ cm⁻², which seriously degrades the quality of GaN crystal, and reduces illumination efficiency and the lifespan of LED. Secondly, because sapphire is an insulator with an electrical resistivity greater than 10¹¹Ω cm at room temperature, it is not suitable to be used for forming devices having vertical structures. Sapphire is usually only used to prepare N-type and P-type electrodes on the epitaxial layer, but it reduces effective lighting area, increases the lithography and etching processes during the fabrication of the devices, and reduces the material utilization. Moreover, sapphire has a poor thermal conductivity of about 0.25 W/cm K at 1000° C., which significantly affects performances of GaN-based devices, especially the large-area and high-power devices in which heat dissipation is required. Furthermore, sapphire has a high hardness and its lattice has a 30 degree angle relative to the lattice of GaN crystal, it is difficult to obtain a cleavage plane of the InGaN epitaxial layer to obtain a cavity surface during the fabrication of GaN-based Laser Diode (LD).

Comparing to sapphire, a SiC substrate has smaller lattice mismatch to GaN. However, GaN—SiC hetero-epitaxial growth still generates misfit dislocations and thermal misfit dislocations. Moreover, SiC is expensive, making it unsuitable for many GaN-based optoelectronic devices. In recently years, Si has also been studied as a substrate for the epitaxial growth of GaN crystals. However, Si has cubic crystalline lattice while GaN has a hexagonal crystalline lattice. Si has a lattice mismatch to GaN even larger than sapphire/GaN, which makes it difficult to support epitaxial growth of GaN material. The GaN layer grown on Si substrates faces serious problems such as cracking; the crystal growth thickness usually cannot exceed 4 μm.

Recently, GaN mono-crystalline substrate has been developed for growing GaN optoelectronic devices. The GaN mono crystal s on the substrate allows iso-epitaxial growth of GaN crystals and can improve the quality of epitaxially grown GaN crystal. Moreover, the good thermal conductivity of the GaN microcrystals allows the formation of vertical structure LED on such substrates. The properties of the devices are improved under large current injections. However, the high cost of the GaN mono-crystalline substrate severely restricts its usage in LED devices. While a 2 inch wide high power LED epitaxial sheet is typically less than 100 dollars, the price for a 2 inch wide GaN mono-crystalline substrate can reach 2000 dollars.

There is therefore a long-felt need for a substrate that can provide expitaxial growth of GaN crystals for fabricating optoelectronic devices without or minimizing the issues discussed above.

### SUMMARY OF THE INVENTION

The present application provides new types of composite substrates and associate methods for growing GaN crystals that can reduce or eliminate the above described problems. The disclosed composite substrate includes a thermally and electrically conductive layer, and a mono-crystalline GaN layer 2 on the thermally and electrically conductive layer.

The disclosed methods, materials, and structures enable iso-epitaxial growth of GaN crystals on a substrate, improve the quality of the grown GaN crystals, and reduce cost. The disclosed methods, materials, and structures also allow vertical device structures being directly formed on the disclosed substrates.

The disclosed methods, materials, and structures can be used in the fabrication of a wide range of optoelectronic devices.

The composite substrate of the present invention can be directly used for the epitaxial-growth of GaN epitaxial sheets, and for the preparation of a vertical structure LED device. The disclosed methods have the one or more following additional advantages compared with conventional technologies:

First, the disclosed methods are much improved over the most commonly used GaN expitaxial growth on sapphire substrates. The sapphire substrate has low electrical and thermal conductivities, which makes difficult or impossible for growing a vertical structure LED device on such substrate. The planar structure LEDs grown on sapphire substrates do not dissipate heat well and are not suitable for high power devices. Additionally, sapphire substrate has a different lattice from GaN, which affects the quality of GaN crystals grown on these substrates.

In contrast, the disclosed composite substrate has a GaN layer that enables iso-epitaxial growth of GaN crystals with improved crystalline quality and thus increased quantum efficiency. Moreover, the composite substrate includes a thermally and electrically conductive layer, which allows the formation a vertical structure LED devices, which greatly increases device efficiency and device density compared to conventional sapphire-based technologies.

The disclosed composite substrate is also advantageous over the conventional Si and SiC substrates. Although these conventional substrates permit epitaxial growth vertical GaN device structures, the GaN crystal growth is heteroepitaxy, which affects crystalline quality of GaN. The lattice mismatch is especially severe for the Si substrate; AlGaN layers are often inserted between the epitaxy grown GaN crystal and the Si substrate to relax stress. The GaN crystal can hardly grow thicker than 3-4 μm on Silicon substrate. On the other hand, although the lattice constant of a SiC substrate is close to a GaN crystal, it is difficult to prepare SiC crystals, and costs are high. In comparison, the disclosed composite substrate enables iso-epitaxial growth of GaN crystals, which offers superior crystalline quality and makes it suitable for a wide range of applications.

The disclosed composite substrate is also a significant improvement over mono-crystalline GaN substrate. Although both substrates provide iso-epitaxy growth of GaN crystals, crystalline quality and thermal dissipation are greatly improved in the disclosed composite substrate by employing two substrate layers of different materials. By using a conductive layer and a thin mono-crystalline GaN substrate, the disclosed composite substrate significantly reduces material cost compared to mono-crystalline GaN substrates.

In summary, the disclosed composite substrate has a combination of advantageous properties of enabling iso-epitaxy GaN growth, high and improved crystalline quality, compatibility with vertical structure devices, and greatly reduced cost. These advantages should enable the disclosed composite substrate for a wide range of device applications.

These and other aspects, their implementations and other features are described in detail in the drawings, the description and the claims.

### BRIEF DESCRIPTION OF THE DRAWINGS

FIG. 1 is a cross-sectional diagram of a composite substrate for GaN growth in accordance to the present invention.

FIG. 2 is a cross-sectional diagram of another composite substrate including a reflective layer in accordance to the present invention.

FIG. 3 is a cross-sectional diagram of another composite substrate including a reflective layer in accordance to the present invention.

FIG. 4 is a cross-sectional diagram of another composite substrate including a periodic grating or a periodic photonic lattice structures in the reflective layer.

FIGS. 5A-5B are perspective diagrams showing a reflective layer respectively having, on its surface, triangular pyramidal recesses (FIG. 5A) and cylindrical recess (FIG. 5B).

FIG. 6 is a schematic diagram showing the steps of bonding a Si substrate to a GaN crystal, and lifting off a sapphire substrate as described in Implementation Example 1.

FIG. 7 is a schematic diagram showing the step of bonding a WCu substrate to a GaN crystal and removing Si substrate from the GaN crystal at high temperature as described in Implementation Example 1.

FIGS. 8A-8D are cross-sectional diagrams showing the preparation of GaN/WCu, GaN/MoCu, and GaN/SiC composite substrates respectively described in Implementation Examples 2, 3, and 6.

FIGS. 9A-9B are cross-sectional diagrams showing the preparation of a GaN/MoCu composite substrate including a metal reflective layer as described in Implementation Example 4.

FIGS. 10A-10B are cross-sectional diagrams showing the preparation of a composite substrate in which a GaN layer is bonded with Si substrate through Van der Waals force as described in Implementation Example 5.

FIGS. 11A-11D are cross-sectional diagrams showing the preparation of a composite substrate in which the GaN layer is bonded with AlSi substrate through AuAu bond as described in Implementation Example 7.

FIG. 12 is a photograph of a composite substrate prepared by the presently disclosed method in which the mono-crystalline GaN layer is bonded with a metal substrate.

### DETAILED DESCRIPTION OF THE INVENTION

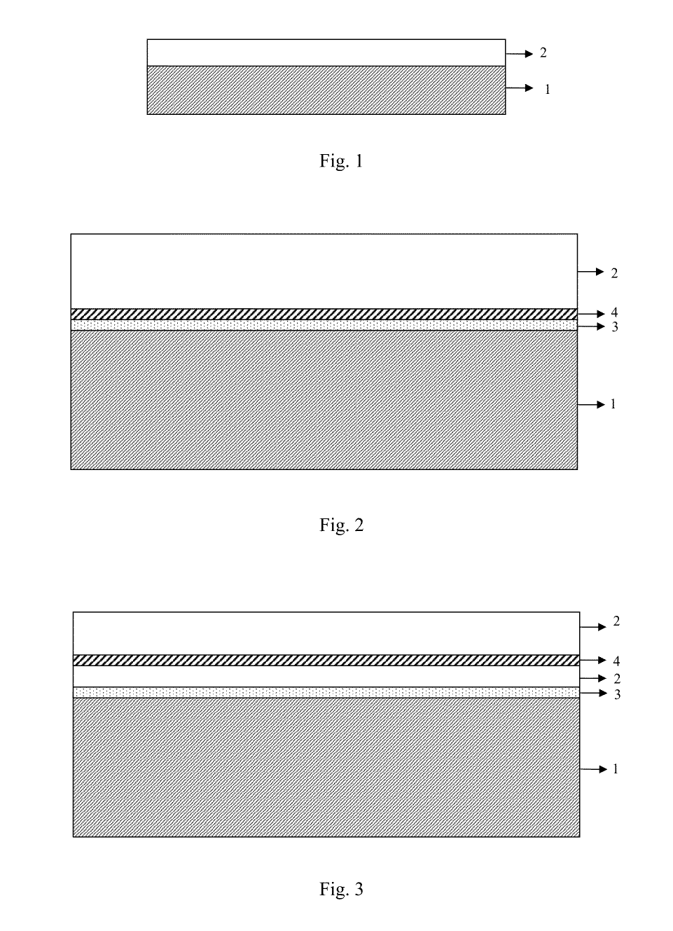

Referring to FIG. 1, a composite substrate includes a thermally and electrically conductive layer 1, and a mono-crystalline GaN layer 2 bonded on to the thermally and electrically conductive layer 1.

The thermally and electrically conductive layer has a thickness in range of 10˜3000 μm, preferably 50˜400 μm. Materials suitable for the thermally and electrically conductive layer 1 are required to have several characteristics: (1) a melting point greater than 1000° C., or nearly in solid state at 1000° C.; and (2) high thermal and high electrical conductivities.

Based on the above requirements, examples of materials suitable for the thermally and electrically conductive layer 1 include metal elements such as W, Ni, Mo, Pd, Au, and Cr, or alloys or quasi alloys of the above metals, or alloy of the above metals with Cu, such as WCu alloy, MoCu alloy, and NiCu alloy. Other materials suitable for the thermally and electrically conductive layer include Si crystalline, SiC crystalline, and AlSi crystalline.

The mono-crystalline GaN layer 2 has a thickness in a range of 0.1˜100 μm, preferably 1˜50 μm. The GaN crystal in the mono-crystalline GaN layer 2 is in the form of a mono crystal.

The thermally and electrically conductive layer 1 can be bonded with the mono-crystalline GaN layer 2 through rigid bonding or flexible bonding. If the bonding is a rigid van der Waals force bonding, the thermal expansion coefficient of the thermally and electrically conductive layer 1 should be close to (i.e. within 10%) the thermal expansion coefficient of the mono-crystalline GaN layer 2. The thermally and electrically conductive layer can also be bonded with the mono-crystalline GaN layer 2 through a flexible medium, which is required to have a melting point greater than 1000° C., and sufficient ductility to relax stress. Examples of such flexible medium includes a layer of Au—Au bonds, or bonds between W, Pd, Ni, or other high-temperature metals, with a layer thickness ranged 0.5˜5 μm. Such metallic medium bonding layer can relax the thermal stress produced by the different thermal expansions between the mono-crystalline GaN layer 2 and the thermally and electrically conductive layer 1. Thus, when bonded with the flexible medium in between, the thermal expansion coefficient of the thermally and electrically conductive layer 1 is not required to be close to that of the mono-crystalline GaN layer 2.

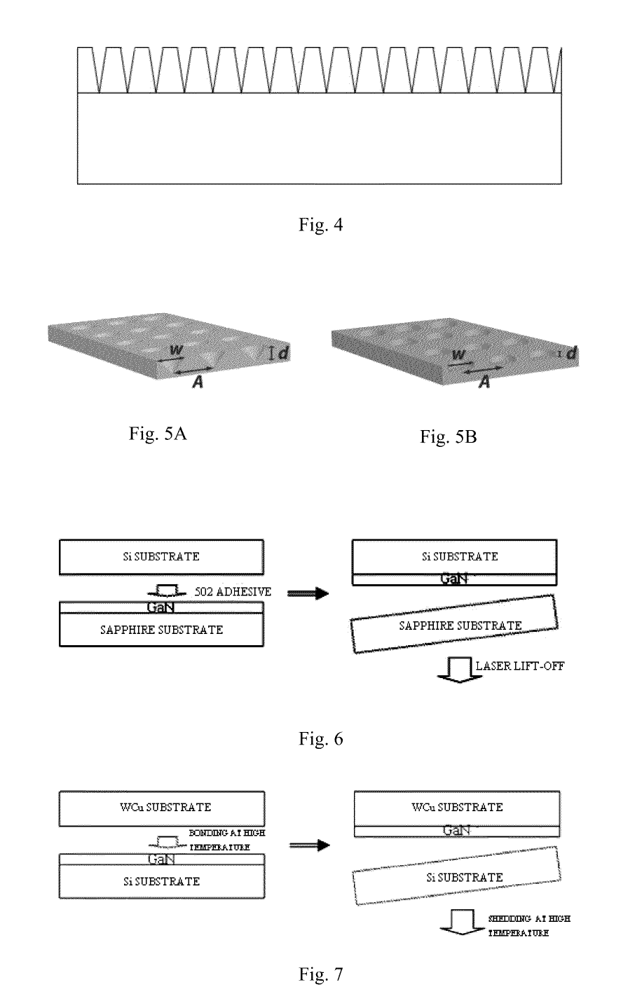

Furthermore, a composite substrate can include a reflective layer 4, located inside, in the lower portion, or at a lower surface of the mono-crystalline GaN layer 2. The reflective layer 4 can be sandwiched at the interface between the mono-crystalline GaN layer 2 and the thermally and electrically conductive layer 1. Referring to FIG. 2, the reflective layer 4 can also be located between a bonding layer 3 and the mono-crystalline GaN layer 2. The bonding layer 3 is positioned between the thermally and electrically conductive layer 1 and the reflective layer 4. As shown in FIG. 3, [what is the white layer between 3 and 4 in FIG. 3?] the reflective layer 4 can also be located inside or in the lower portion of the mono-crystalline GaN layer 2. If the reflective layer 4 is located at the side of the bonding layer that is close to the mono-crystalline GaN layer 2, the reflective layer 4 can be formed by a metallic material such as Pd, Cr, and so on. If the reflective layer is located inside or at the lower portion of the mono-crystalline GaN layer 2, the reflective layer 4 can be in a periodic or quasi-periodic structure, as shown in FIG. 4. Examples for such periodic or quasi-periodic structure include grating structures or photonic lattice structures.

The grating structures are micron-scale periodic structures. The photonic lattice structures are nano-scale periodic structures which can be periodic protrusions or recesses. The protrusions and the recesses can have conical shapes, cylindrical shapes, or triangular pyramidal shapes. The protrusions and the recesses can be disposed periodically, quasi-periodically, or aperiodic. FIG. 5A shows a reflective layer having triangular pyramidal recesses distributed periodically. FIG. 5B a reflective layer having cylindrical recesses distributed periodically. These micron-scale or nano-scale periodic structures can be 10 nm˜50 μm, preferably 200 nm˜10 μm. In FIGS. 5A and 5B, w and d are respectively the width and the depth of the recesses; A is the period or the mean distance between adjacent recesses, wherein A>w.

The micron-scale or nano-scale structures in the reflective layers are required to be heat-resistant, for example, having melting point greater than 1000° C. The materials forming the structures have a refractive index different from that of the microcrystalline GaN layer 2. For example, suitable materials include SiO₂ or SiN that can grow in a crystalline phase on the mono-crystalline GaN layer 2, or coated on or embedded in the mono-crystalline GaN layer 2. These materials have refractive indices different from the mono-crystalline GaN layer 2, and generate effective total internal reflections. The average refractive index at the interface between thermally and electrically conductive layer 1 and the mono-crystalline GaN layer 2 is effectively increased by the periodic structures.

In some embodiments, the periodic structures located at the lower portion or in the lower surface of the mono-crystalline GaN layer 2 are made of the same material as the mono-crystalline GaN layer 2. These periodic patterns can also reflect light and can act as reflective layers.

The reflective layer plays an important role on the GaN-based devices epitaxially grown on the disclosed composite substrate. In the light emitting devices, the light from active layer can usually be emitted in a 360 degree angular range. Without reflective layers, 40% of the emitted light can be absorbed by the thermally and electrically conductive layer, which presents a significant waste. The incorporation of the reflective layers to the disclosed composite substrate can thus increase light emission efficiency more than 30%.

The present disclosure is illustrated by the following implementation examples. It should be understood, however, that disclosed invention is not limited by the examples below. Other implementations, variations, modifications and enhancements to the described examples and implementations can be made without deviating from the spirit of the present invention.

### IMPLEMENTATION EXAMPLE 1

### A Metal Composite Substrate Comprising a WCu Alloy Layer and a GaN Layer Bonded with Au—Au Bonds

In the first steps, a 4 μm thick GaN mono crystal is epitaxially grown on a 2 inch 430 μm thick sapphire substrate using Metal-organic Chemical Vapor Deposition (MOCVD). Next, a GaN crystal is grown to a crystal thickness of 10 μm using hydride vapor phase epitaxy (HVPE) technique.

In the second steps, referring to FIG. 6, a surface of the GaN mono crystal is bonded to a 2 inch 400 μm thick Si substrate using 502 instant adhesive. The Si substrate is used as a transfer and support substrate. The sapphire substrate is then lifted off from the GaN crystal using laser lift-off technology, leaving an assembly comprising a GaN mono crystal bonded on the Si substrate.

In the third steps, a 1 μm Au layer is deposited simultaneously on the surfaces of mono-crystalline GaN layer and the Si substrate 6, and the surfaces of a WCu alloy substrate. The WCu alloy substrate is then bonded to the surface of the GaN mono crystal via Au—Au bonding, as shown in FIG. 7, at 300° C. under a pressure of 5 tons for through 15 minutes. After bonding, the 502 instant adhesive is carbonized at high temperature, which allows Si substrate to separate from GaN/WCu composite substrate.

After surface cleaning, a GaN/WCu composite substrate is obtained. The composite substrate includes a 150 μm thick WCu alloy layer with a W:Cu mass ratio of 15:85. The WCu alloy layer is bonded with a layer of 10 μm thick GaN mono crystal layer by AuAu bond. The thickness of the bonding layer is 2 μm.

### IMPLEMENTATION EXAMPLE 2

### A Metal Composite Substrate Comprising a WCu Alloy Layer and a GaN Layer Bonded with Au—Au Bonds

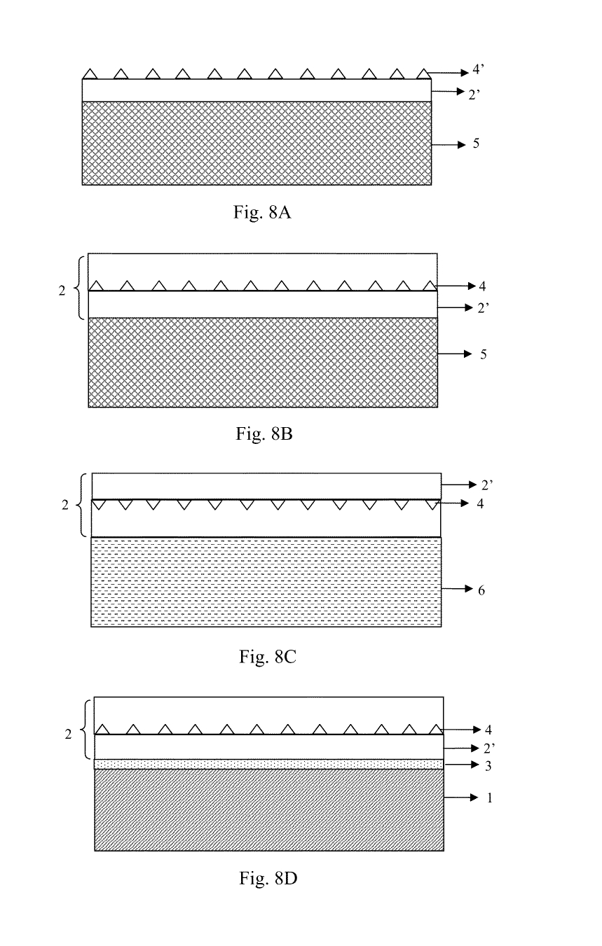

In the first steps, as shown in FIG. 8A, a GaN mono crystal thin film 2′ is epitaxially grown on a 2 inch 430 μm thick sapphire substrate 5 using MOCVD. The GaN mono crystal thin film 2′ is about 4 μm in thickness.

In the second steps, a 1 μm layer of SiO₂ thin film is grown on the surface of the GaN mono crystal layer using plasma enhanced chemical vapor deposition (PECVD) technology. The SiO₂ thin layer is then patterned with lithography and dry etched into periodic conical structures 4′ spaced by a period of about 3 μm, as shown in FIG. 8A. The conical structures 4′ have a base diameter of about 2.5 μm and a height about 1 μm. The surface of the GaN mono crystal thin film 2′ is exposed in the space between the conical structures 4′. The periodic conical structures 4′ form as a reflective layer 4.

In the third steps, as shown in FIG. 8B, a GaN crystal layer is continuously grown using HVPE technology on the surface of the GaN mono crystal thin film 2′ and the reflective layer 4 composed of periodic conical structures 4′. The newly grown GaN crystal and the GaN mono crystal thin film 2′ together forms a mono-crystalline GaN layer 2 having a total thickness of about 10 μm. The reflective layer 4 is embedded inside the mono-crystalline GaN layer 2.

In the fourth steps, as shown in FIG. 8C, the surface of the mono-crystalline GaN layer 2 is bonded with a 2 inch 400 μm thick Si substrate 6 by an instant adhesive. The Si substrate 6 is used as a transfer and support substrate. The sapphire substrate 5 is then lifted off by laser lift-off technology, leaving the mono-crystalline GaN layer 2 bonded to the Si substrate 6.

In the fifth steps, a 1 μm Au layer is deposited simultaneously on the surfaces of the mono-crystalline GaN layer 2 and the Si substrate 6, and the surfaces of a separate 150 μm thick WCu alloy layer (substrate) 1. The WCu alloy layer 1 is then bonded to the surface of the mono-crystalline GaN layer 2 via Au—Au bonding, as shown in FIG. 8D, at 300° C. under a pressure of 5 tons for through 15 minutes. After bonding, the instant adhesive is carbonized at high temperature, which allows Si substrate 6 to separate from GaN/WCu composite substrate.

At last, as shown in FIG. 8D, after surface cleaning, a composite substrate is obtained which includes a 150 μm thick WCu alloy layer 1 with a W:Cu mass ratio of 15:85. The WCu alloy layer 1 is bonded with a layer of 10 μm thick GaN mono crystal layer by Au—Au bond, wherein the bonding layer 3 is 2 μm in thickness. The reflective layer 4 is embedded in the mono-crystalline GaN layer 2 and is at 4 μm distance from the bonding layer 3. The reflective layer 4 includes 1 μm high and 2.5 μm wide conical SiO₂ structures spaced at a 3 μm period.

### IMPLEMENTATION EXAMPLE 3

### A Metal Composite Substrate Comprising a MoCu Alloy Layer and a GaN Layer Bonded with Au—Au Bonds

In the first steps, as shown in FIG. 8A, a GaN mono crystal thin film 2′ is epitaxially grown on a 2 inch 430 μm thick sapphire substrate 5 using MOCVD. The GaN mono crystal thin film 2′ is about 4 μm in thickness.

In the second steps, a 1 μm layer of SiO₂ thin film is grown on the surface of the GaN mono crystal thin film 2′ using PECVD technology. The SiO₂ thin layer is then patterned with lithography and dry etched into periodic conical structures 4′ spaced by a period of about 3 μm, as shown in FIG. 8A. The conical structures 4′ have a base diameter of about 2.5 μm and a height about 1 μm. The surface of the GaN mono crystal thin film 2′ is exposed in the space between the conical structures 4′. The periodic conical structures 4′ form as a reflective layer 4.

In the third steps, as shown in FIG. 8B, a GaN crystal layer is continuously grown using HVPE technology on the surface of the GaN mono crystal thin film 2′ and the reflective layer 4 composed of periodic conical structures 4′. The newly grown GaN crystal and the GaN mono crystal thin film 2′ together forms a mono-crystalline GaN layer 2 having a total thickness of about 10 μm. The reflective layer 4 is embedded inside the mono-crystalline GaN layer 2.

In the fourth steps, as shown in FIG. 8C, the surface of the mono-crystalline GaN layer 2 is bonded with a 2 inch 400 μm thick Si substrate 6 by an instant adhesive. The Si substrate 6 is used as a transfer and support substrate. The sapphire substrate 5 is then lifted off by laser lift-off technology, leaving the mono-crystalline GaN layer 2 bonded to the Si substrate 6.

In the fifth steps, a 1 μm Au layer is deposited simultaneously on the surfaces of the mono-crystalline GaN layer 2 and the Si substrate 6, and the surfaces of a separate 150 μm thick MoCu alloy layer (substrate) 1. The MoCu alloy layer 1 is then bonded to the surface of the mono-crystalline GaN layer 2 via Au—Au bonding, as shown in FIG. 8D, at 300° C. under a pressure of 5 tons for through 15 minutes. After bonding, the instant adhesive is carbonized at high temperature, which allows Si substrate 6 to separate from GaN/MoCu composite substrate.

At last, as shown in FIG. 8D, after surface cleaning, a composite substrate is obtained which includes a 150 μm thick MoCu alloy layer 1 with a Mo:Cu mass ratio of 20:80. The MoCu alloy layer 1 is bonded with a layer of 10 μm thick mono-crystalline GaN layer 2 by Au—Au bond, wherein the bonding layer 3 is 2 μm in thickness. The reflective layer 4 is embedded in the mono-crystalline GaN layer 2 and is at a 4 μm distance from the bonding layer 3. The reflective layer 4 includes 1 μm high and 2.5 μm wide conical SiO₂ structures spaced at a 3 μm period.

### IMPLEMENTATION EXAMPLE 4

### A Metal Composite Substrate Comprising a MoCu Alloy Layer and a GaN Layer Bonded with Ni—Ni Bonds

In the first steps, a mono-crystalline GaN layer 2 is epitaxially grown on a 2 inch 430 μm thick sapphire substrate 5 using MOCVD. The mono-crystalline GaN layer 2 is about 4 μm in thickness.

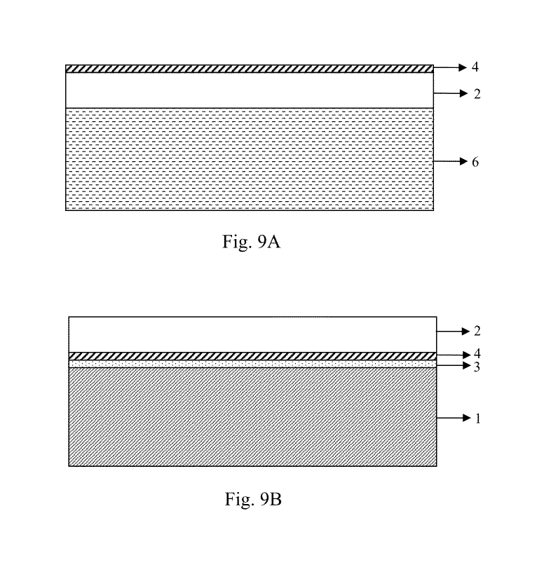

In the second steps, as shown in FIG. 9A, the surface of the mono-crystalline GaN layer 2 is bonded with a 2 inch 400 μm thick Si substrate 6 by an instant adhesive. The Si substrate 6 is used as a transfer and support substrate. The sapphire substrate 5 is then lifted off by laser lift-off technology, leaving the mono-crystalline GaN layer 2 bonded to the Si substrate 6.

In the third steps, a reflective layer 4 if formed by depositing a 200 nm thick Pd metal layer on the surface of the mono-crystalline GaN layer 2 on the Si substrate 6, as shown in FIG. 9A.

In the fourth steps, as shown in FIG. 9A, a 2 μm Ni is deposited simultaneously on the surfaces of the reflective layer 4 and the Si substrate 6, and the surfaces of a separate 150 μm thick MoCu alloy layer (substrate) 1. The MoCu alloy layer (substrate) 1 is bonded at 800°, under a 15 ton pressure, for 15 minutes to the reflective layer 4 with a Ni bonding layer 3 in between. After bonding, the instant adhesive is carbonized at high temperature, which allows Si substrate 6 to separate from GaN/MoCu composite substrate.

At last, as shown in FIG. 9B, after surface cleaning, a composite substrate is obtained which includes a 150 μm thick MoCu alloy layer 1 with a Mo:Cu mass ratio of 20:80. The MoCu alloy layer 1 is bonded by Ni—Ni bond to the reflective layer 4 which is bonded to a 4 μm thick mono-crystalline GaN layer 2. The bonding layer 3 is 4 μm in thickness.

### IMPLEMENTATION EXAMPLE 5

### A Composite Substrate Comprising a Si Substrate and a GaN Layer Bonded by Van Der Waals Force

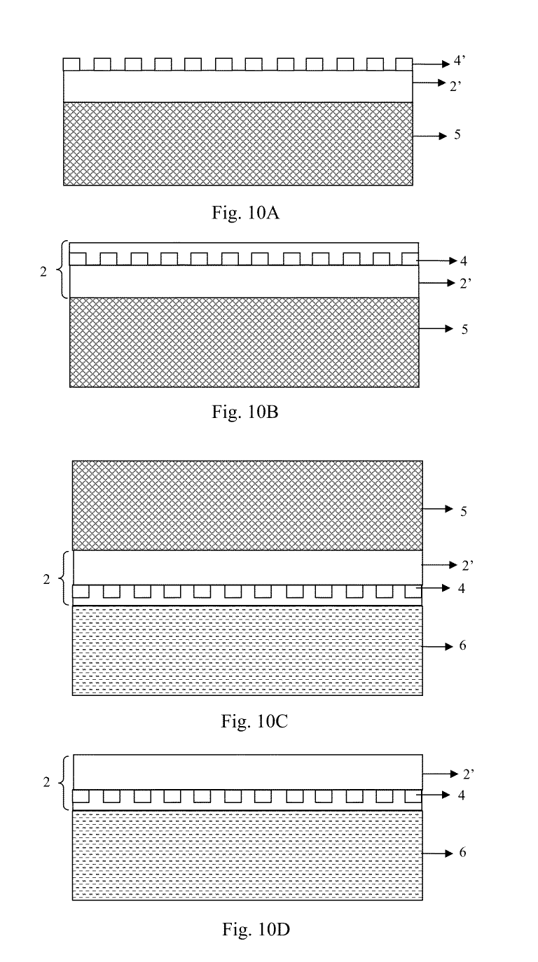

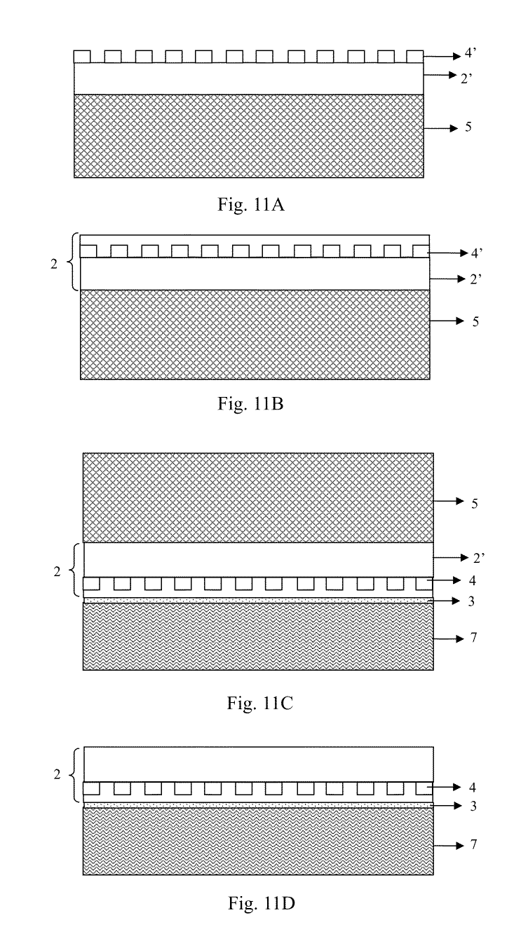

In the first steps, as shown in FIG. 10A, a GaN mono crystal thin film is epitaxially grown on a 2 inch 430 μm thick sapphire substrate 5 using MOCVD. The GaN mono crystal thin film 2′ is about 4 μm in thickness.

In the second steps, a GaN crystal layer 2′ is continuously grown using HVPE technology on the surface of the GaN mono crystal thin film until the total thickness of the GaN crystal reaches 46 μm.

In the third steps, a 1 μm thick SiO₂ thin film is grown by PECVD technology on the surface of the GaN crystal layer 2′. The SiO₂ thin layer is then patterned with lithography and dry etched into periodic cylindrical structures 4′ spaced by a period of about 3 μm, as shown in FIG. 10A. The cylindrical structures 4′ have a base diameter of about 2 μm and a height about 1 μm. The surface of the GaN crystal layer 2′ is exposed in the space between the cylindrical structures 4′. The periodic cylindrical structures 4′ form a reflective layer 4.

In the fourth steps, as shown in FIG. 10B, a GaN crystal layer is continuously grown using HVPE technology on the surface of the GaN crystal layer 2′ and the reflective layer 4 composed of periodic cylindrical structures 4′. The newly grown GaN crystal and the GaN mono crystal thin film 2′ together forms a mono-crystalline GaN layer 2 having a total thickness of about 50 μm. The reflective layer 4 is embedded inside the mono-crystalline GaN layer 2.

In the fifth steps, the surface of the mono-crystalline GaN layer 2 is bonded with a 2 inch 400 μm thick Si substrate 6 by a van der Waals force, at 900° C. under pressure of 20 tons for through 30 minutes, forming a sapphire/GaN/Si assembly, as shown in FIG. 10C.

In the sixth steps, the sapphire substrate 5 is then lifted off by laser lift-off technology, leaving the mono-crystalline GaN layer 2 bonded to the Si substrate 6, as shown in FIG. 10D.

At last, as shown in FIG. 10D, a composite substrate is obtained which includes a layer of 400 μm thick Si substrate 6, bonded with a layer of 50 μm thick GaN mono crystal 2 by van der Waals force. The reflective layer 4 is embedded in the mono-crystalline GaN layer 2 and is at a 4 μm distance from the bonding layer 3. The reflective layer 4 includes 1 μm high and 2 μm wide cylindrical SiO₂ structures spaced at a 3 μm period.

### IMPLEMENTATION EXAMPLE 6

### A Metal Composite Substrate Comprising a SiC Layer and a GaN Layer Bonded with Pd—Pd Bonds

In the first steps, as shown in FIG. 8A, a GaN mono crystal thin film 2′ is epitaxially grown on a 2 inch 430 μm thick sapphire substrate 5 using MOCVD. The GaN mono crystal thin film 2′ is about 4 μm in thickness.

In the second steps, a 1 μm layer of SiO₂ thin film is grown on the surface of the GaN mono crystal layer using PECVD technology. The SiO₂ thin layer is then patterned with lithography and dry etched into periodic conical structures 4′ spaced by a period of about 3 μm, as shown in FIG. 8A. The conical structures 4′ have a base diameter of about 2.5 μm and a height about 1 μm. The surface of the GaN mono crystal thin film 2′ is exposed in the space between the conical structures 4′. The periodic conical structures 4′ form as a reflective layer 4.

In the third steps, as shown in FIG. 8B, a GaN crystal layer is continuously grown using HVPE technology on the surface of the GaN mono crystal thin film 2′ and the reflective layer 4 composed of periodic conical structures 4′. The newly grown GaN crystal and the GaN mono crystal thin film 2′ together forms a mono-crystalline GaN layer 2 having a total thickness of about 10 μm. The reflective layer 4 is embedded inside the mono-crystalline GaN layer 2.

In the fourth steps, as shown in FIG. 8C, the surface of the mono-crystalline GaN layer 2 is bonded with a 2 inch 400 μm thick Si substrate 6 by an instant adhesive. The Si substrate 6 is used as a transfer and support substrate. The sapphire substrate 5 is then lifted off by laser lift-off technology, leaving the mono-crystalline GaN layer 2 bonded to the Si substrate 6.

In the fifth steps, a 1 μm Pd layer is deposited simultaneously on the surfaces of the mono-crystalline GaN layer 2 and the Si substrate 6, and the surfaces of a separate 150 μm thick SiC alloy layer (substrate) 1. The SiC alloy layer 1 is then bonded to the surface of the mono-crystalline GaN layer 2 via Pd—Pd bonding, as shown in FIG. 8D, at 800° C. under a pressure of 8 tons for through 15 minutes. After bonding, the instant adhesive is carbonized at high temperature, which allows Si substrate 6 to separate from GaN/SiC composite substrate.

At last, as shown in FIG. 8D, after surface cleaning, a composite substrate is obtained which includes a 150 μm thick SiC alloy layer. The SiC alloy layer 1 is bonded with a layer of 10 μm thick mono-crystalline GaN layer 2 by Pd—Pd bonds, wherein the bonding layer 3 is 2 μm in thickness. The reflective layer 4 is embedded in the mono-crystalline GaN layer 2 and is at a 4 μm distance from the bonding layer 3. The reflective layer 4 includes 1 μm high and 2.5 μm wide conical SiO₂ structures spaced at a 3 μm period.

### IMPLEMENTATION EXAMPLE 7

### A Metal Composite Substrate Comprising a AlSi Layer and a GaN Layer Bonded with Au—Au Bonds

In the first steps, as shown in FIG. 8A, a GaN mono crystal thin film 2′ is epitaxially grown on a 2 inch 430 μm thick sapphire substrate 5 using MOCVD. The GaN mono crystal thin film 2′ is about 6 μm in thickness.

In the second steps, a 1 μm layer of SiO₂ thin film is grown on the surface of the GaN mono crystal thin film 2′ using PECVD technology. The SiO₂ thin layer is then patterned with lithography and dry etched into periodic conical structures 4′ spaced by a period of about 3 μm, as shown in FIG. 11A. The cylindrical structures 4′ have a diameter of about 2 μm and a height about 1 μm. The surface of the GaN mono crystal thin film 2′ is exposed in the space between the cylindrical structures 4′. The periodic cylindrical structures 4′ form as a reflective layer 4.

In the third steps, as shown in FIG. 11B, a GaN crystal layer is continuously grown using HVPE technology on the surface of the GaN mono crystal thin film 2′ and the reflective layer 4 composed of periodic conical structures 4′. The newly grown GaN crystal and the GaN mono crystal thin film 2′ together forms a mono-crystalline GaN layer 2 having a total thickness of about 10 μm. The reflective layer 4 is embedded inside the mono-crystalline GaN layer 2.

In the fourth steps, a 1 μm Au layer is deposited simultaneously on the surfaces of the mono-crystalline GaN layer 2 and the sapphire substrate 5, and the surfaces of a separate 200 μm thick AlSi alloy layer (substrate) 7. The AlSi alloy layer 7 is then bonded to the surface of the mono-crystalline GaN layer 2 via Au—Au bonding in a bonding layer 3, as shown in FIG. 11C, at 300° C. under a pressure of 5 tons for through 15 minutes.

In the fifth steps, after bonding, the sapphire substrate is lifted off by laser lift-off technology, leaving a composite substrate with GaN/AlSi bonded by the bonding layer 3, as shown in FIG. 11D.

At last, as shown in FIG. 11D, after surface cleaning, a composite substrate is obtained which includes a 200 μm thick AlSi layer 7 with a Al:Si mass ratio of 30:70. The AlSi layer 7 is bonded with a layer of 10 μm thick mono-crystalline GaN layer 2 by Au—Au bond, wherein the bonding layer 3 is about 4 μm in thickness. The reflective layer 4 is embedded in the mono-crystalline GaN layer 2. The reflective layer 4 includes 1 μm high and 2 μm wide cylindrical SiO₂ structures spaced at a 3 μm period.

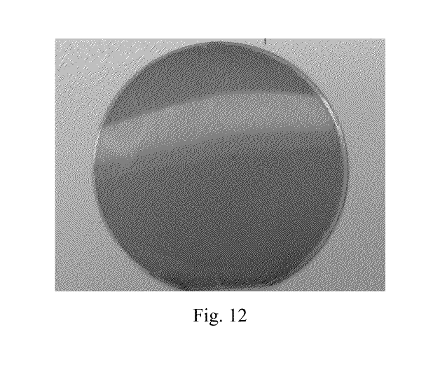

A photograph of an exemplified composite substrate prepared by one of the presently disclosed methods is shown in FIG. 12. The composite substrate includes a mono-crystalline GaN layer bonded with a metal substrate.

While this document contains many specifics, these should not be construed as limitations on the scope of an invention that is claimed or of what can be claimed, but rather as descriptions of features specific to particular embodiments. Certain features that are described in this document in the context of separate embodiments can also be implemented in combination in a single embodiment. Conversely, various features that are described in the context of a single embodiment can also be implemented in multiple embodiments separately or in any suitable sub-combination. Moreover, although features can be described above as acting in certain combinations and even initially claimed as such, one or more features from a claimed combination can in some cases be excised from the combination, and the claimed combination can be directed to a sub-combination or a variation of a sub-combination.

It will thus be seen that the objects of the present invention have been fully and effectively accomplished. Its embodiments have been shown and described for the purpose of illustrating the functional and structural principles of the present invention and is subject to change without departure from such principles. Therefore, this invention includes all modifications encompassed within the spirit and scope of the following claims.

What is claimed is:

1. A composite substrate used for GaN growth, comprising a thermally and electrically conductive layer and a GaN mono-crystalline layer located on the thermally and electrically conductive layer, wherein the melting point of the said thermally and electrically conductive layer is greater than 1000° C.

2. The composite substrate of claim 1, is characterized that, the thickness of the said thermally and electrically conductive layer is 10 μm˜3000 μm, preferably 50 μm˜400 μm; the thickness of the said GaN mono-crystalline layer is 0.1 μm˜100 μm, preferably 1 μm˜50 μm.

3. The composite substrate of claim 1, is characterized that, the materials for the said thermally and electrically conductive layer are elementary metals or alloy or Quasi-alloys with the melting point greater than 1000° C.

4. The composite substrate of claim 1, is characterized that, the materials of the said thermally and electrically conductive layer choose from one of metal W, Ni, Mo, Pd, Au and Cr or alloys of more of them, or the alloys of one or more of these metals with Cu, or Si crystals, SiC crystals or AlSi crystals.

5. The composite substrate of claim 1, is characterized that, there is a flexible medium bonding layer between the said thermally and electrically conductive layer and GaN mono-crystalline layer.

6. The composite substrate of claim 1, is characterized that, the said composite substrate comprises a reflecting layer, which is located at an inner side, a bottom part, or a bottom surface of the GaN mono-crystalline layer, the bottom surface of the GaN mono-crystalline layer is the surface of the GaN mono-crystalline layer connected with the thermally and electrically conductive layer.

7. The composite substrate of claim 6, is characterized that, there is a bonding layer, a reflecting layer and a GaN mono-crystalline layer on the said thermally and electrically conductive layer in order.

8. The composite substrate of claim 7, is characterized that, the said reflecting layer is a metal reflecting layer.

9. The composite substrate of claim 6, is characterized that, the said reflecting layer is a periodic structure layer with grating structures or photonic lattice structures, located at an inner side or a bottom part of the GaN mono-crystalline layer.

10. The composite substrate of claim 9, is characterized that, the said reflecting layer is a periodic structure formed by materials with a refractive index different from GaN and a melting point greater than 1000° C., embedded in the GaN mono-crystalline layer.

11. The composite substrate of claim 10, is characterized that, the said reflecting layer is a periodic structure formed by SiO₂ or SiN, embedded in the GaN mono-crystalline layer.

12. The composite substrate of claim 9, is characterized that, the said reflecting layer is a periodic pattern formed on the bottom part of the GaN mono-crystalline layer.
